(19) United States
(12) Patent Application Publication
(10) Pub. No.: US 2021/0225643 A1
(43) Pub. Date: Jul. 22, 2021

(54) METHOD FOR DEPOSITION OF SILICON NITRIDE LAYER USING PRETREATMENT, STRUCTURE FORMED USING THE METHOD, AND SYSTEM FOR PERFORMING THE METHOD

(71) Applicant: ASM IP Holding B.V., Almere, NL (US)

(72) Inventors: Aurélie Kuroda, Tokyo (JP); Ryoko Zhang, Odawara-shi (JP); Masaki Tokunaga, Portland, OR (US); Ling-Chi Hwang, Tokyo (JP); Makoto Igarashi, Tokyo (JP)

(21) Appl. No.: 17/152,592

(22) Filed: Jan. 19, 2021

Related U.S. Application Data
(60) Provisional application No. 62/963,487, filed on Jan. 20, 2020.

(51) Int. Cl. H01L 21/02; C23C 16/34; C23C 16/44; C23C 16/509

(52) U.S. Cl. CPC H01L 21/02312; H01L 21/0217; C23C 16/5096; C23C 16/345; C23C 16/4408; H01L 21/02274

(57) ABSTRACT

Methods and systems for pretreating a surface prior to depositing silicon nitride on the surface are disclosed. Exemplary methods include pretreating the surface by exposing the surface to activated species formed from one or more gases comprising nitrogen and hydrogen. The step of pretreating can additionally include a step of exposing the surface to a gas comprising silicon.

### CROSS-REFERENCE TO RELATED APPLICATIONS

This application claims the benefit of and priority to U.S. Provisional Application No. 62/963,487, filed on Jan. 20, 2020 in the United States Patent and Trademark Office, the disclosure of which is incorporated herein in its entirety by reference.

### FIELD OF INVENTION

The present disclosure generally relates to methods of forming thin films and to structures including the thin films. More particularly, the disclosure relates to methods of depositing silicon nitride layers, to structures including such layers, and to apparatus for depositing the layers.

### BACKGROUND OF THE DISCLOSURE

Features formed using silicon nitride films are used for a wide variety of applications. For example, such features can be used as insulating regions, as etch stop regions, as spacers, to protect trench structures, and for etch-resistant protective regions in the formation of electronic devices.

In some applications, it may be desirable to deposit relatively thin—e.g., less than 10 nm or less than 5 nm thick—and uniform films of silicon nitride on a surface of a substrate. Further, it is often desirable to deposit films of uniform thickness over a three-dimensional surface on a surface of a substrate.

Plasma-enhanced deposition is used in several applications to deposit silicon nitride films to, for example, reduce a deposition temperature and/or increase a deposition rate. Growth incubation of plasma-enhanced deposited silicon nitride films can be highly dependent on a material on a surface of a substrate. By way of example, in the case of depositing silicon nitride over a silicon oxide trench structure using a plasma-enhanced process, up to 4 nm of incubation growth can be observed. This implies that, for a desired 4 nm film growth, a target number of cycles equivalent to 8 nm film may be used to deposit the 4 nm thick film. As a result, productivity is about 50% of desired productivity. Once an initial layer of silicon nitride is deposited onto the surface silicon nitride film, growth can be relatively uniform.

One approach to reducing an incubation time for plasma-enhanced silicon nitride film deposition includes increasing a time that a precursor is fed to a reaction chamber and increasing a time that radio frequency (RF) power is applied during initial deposition cycles of a plasma-enhanced silicon nitride deposition process. However, this approach does not eliminate incubation growth differences between different materials or materials terminated with different bond structures. Further, incubation growth difference can still exist from substrate to substrate. In addition, because a precursor is used during the incubation process, such an approach can result in film growth.

Accordingly, improved methods and systems for forming structures including silicon nitride films are desired. For example, improved methods for uniformly depositing silicon nitride films over a surface of a substrate (which may comprise one or more materials and/or surface-terminated bonds) and systems for performing such methods are desired.

### SUMMARY OF THE DISCLOSURE

Various embodiments of the present disclosure relate to methods of forming features including silicon nitride, to systems for performing the methods, and to the structures including silicon nitride film. While the ways in which various embodiments of the present disclosure address drawbacks of prior methods and systems are discussed in more detail below, in general, various embodiments of the disclosure provide improved methods of depositing silicon nitride using a pretreatment process. Exemplary methods described below provide relatively efficient methods of pretreating a surface of a substrate to allow for relatively uniform deposition incubation times—even across different materials on a surface of a substrate and/or across different substrates. Further, exemplary methods can provide relatively uniform deposition incubation across a feature, such as along a height of a trench or protrusion on a substrate surface.

In accordance with at least one embodiment of the disclosure, a method of forming a silicon nitride layer includes providing a substrate within a reaction chamber, exposing the substrate to activated species formed from one or more gases comprising nitrogen and hydrogen, and depositing a layer of silicon nitride on the substrate within the reaction chamber. The one or more gases comprising nitrogen and hydrogen can include, for example, one or more of nitrogen (N₂), hydrogen (H₂), ammonia, and/or hydrazine, which may be combined with a second gas, such as one or more of argon, helium, and nitrogen. In accordance with examples of these embodiments, the step of depositing a layer of silicon nitride includes a plasma-enhanced deposition process. The step of exposing the substrate to activated species can include a pulsed plasma process—e.g., wherein a power for plasma formation is pulsed. The step of depositing a layer of silicon nitride can include a cyclical process, in which at least one of a reactant and a precursor are exposed to a plasma to form activated species. In accordance with further examples, a reactant is continuously flowed into the reaction chamber during the steps of providing a precursor to the reaction chamber and forming activated reactant species within the reaction chamber.

In accordance with further embodiments of the disclosure, a method of forming a silicon nitride layer includes providing a substrate within a reaction chamber, exposing the substrate to a silicon-containing precursor for thermal adsorption of silicon onto a surface of the substrate, exposing the substrate to activated species formed from one or more gases comprising nitrogen and hydrogen; and depositing a layer of silicon nitride on the substrate within the reaction chamber. In accordance with examples of these embodiments, the silicon precursor includes silicon and hydrogen (e.g., a silane, such as silane, disilane, trisilane, or the like). The step of exposing the substrate to activated species can include a pulsed plasma process—e.g., wherein a power for plasma formation is pulsed. The step of depositing a layer of silicon nitride can include a plasma-enhanced deposition process.

In accordance with additional embodiments of the disclosure, a structure includes a feature including silicon nitride. The feature can be formed using a method as described herein.

In accordance with additional embodiments of the disclosure, a system for performing a method as described herein and/or for forming a structure as described herein is disclosed.

For purposes of summarizing the invention and the advantages achieved over the prior art, certain objects and advantages of the invention may have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein, without necessarily achieving other objects or advantages as may be taught or suggested herein. These and other embodiments will become readily apparent to those skilled in the art from the following detailed description of certain embodiments having reference to the figures, the invention not being limited to any particular embodiment disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method of forming a silicon nitride layer in accordance with at least one embodiment of the disclosure.

FIG. 2 illustrates a structure in accordance with at least one embodiment of the disclosure.

FIG. 3 illustrates RF power application in accordance with examples of the disclosure.

FIG. 4 illustrates film thickness differences of silicon nitride films deposited with and without a pretreatment step in accordance with examples of the disclosure.

FIG. 5 illustrates trench width differences of silicon nitride films deposited with and without a pretreatment step in accordance with examples of the disclosure.

FIG. 6 illustrates silicon nitride thickness differences deposited on silicon oxide and silicon blanket layers as a function of pretreatment time for varying hydrogen concentrations.

FIGS. 7 and 8 illustrate top and sidewall film thickness as a function of pretreatment time.

FIG. 9 illustrates N₂₊ (391 nm) adsorption peak by OES during pretreatment.

FIG. 10 illustrates Hα (656 nm) adsorption peak by OES during pretreatment.

FIG. 11 illustrates film thickness points on a structure.

FIGS. 12 and 13 illustrate top and sidewall film thickness as a function of pretreatment time.

FIG. 14 illustrates a comparison of Ar/NH₃ plasma pretreatment only and a combination of silane thermal adsorption and Ar/NH₃ plasma pretreatment.

FIG. 15 illustrates a system in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed not be limited by the particular disclosed embodiments described below.

As set forth in more detail below, examples of the disclosure provide improved methods and systems for depositing silicon nitride films on a surface of a substrate. Exemplary methods include use of one or more pretreatment processes to provide a desired substrate surface for subsequent deposition. The one or more pretreatment processes can provide for reduced incubation cycles for the subsequent deposition or eliminate an incubation for subsequent silicon nitride deposition and/or can provide for more uniform deposition of silicon nitride over different materials and/or materials formed using different techniques and/or having different thicknesses. Additionally or alternatively, examples of the disclosure can provide improved step coverage of silicon nitride films deposited over features on a surface of a substrate.

As used herein, the term “substrate” can refer to any underlying material or materials that may be used to form, or upon which, a device, a circuit, or a film may be formed. A substrate can include a bulk material, such as silicon (e.g., single-crystal silicon), and can include one or more layers overlying the bulk material. Further, the substrate can include various features, such as trenches, recesses, protrusions, lines, or the like formed within or on at least a portion of the substrate.

As used herein, the term “cyclical deposition” can refer to a sequential introduction of precursors/reactants into a reaction chamber to deposit a layer over a substrate and can include processing techniques, such as atomic layer deposition and cyclical chemical vapor deposition. A reaction chamber can be purged after the introduction of one or more of the precursors and/or reactants.

As used herein, the term “atomic layer deposition” (ALD) can refer to a vapor deposition process in which deposition cycles, typically a plurality of consecutive deposition cycles, are conducted in a process chamber. Generally, during each cycle, a precursor is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Further, purging steps can also be utilized during each cycle to remove excess precursor from the process chamber and/or remove excess reactant and/or reaction byproducts from the process chamber after conversion of the chemisorbed precursor. The term atomic layer deposition, as used herein, is meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor(s)/reactive gas(es), and purge (e.g., inert) gas(es).

As used herein, the term “cyclical chemical vapor deposition” can refer to any process in which a substrate is sequentially exposed to two or more volatile precursors, which react and/or decompose on a substrate to deposit material.

A layer including silicon nitride (SiN) or silicon nitride layer can comprise, consist essentially of, or consist of silicon nitride material. Films consisting of silicon nitride can include an acceptable amount of impurities, such as carbon, chlorine or other halogen, and/or hydrogen, that may originate from one or more precursors used to deposit the silicon nitride layers. As used herein, SiN or silicon nitride refers to a compound that includes silicon and nitrogen. SiN can be represented as SiNₓ, where x varies from, for example, about 0.5 to about 2.0, where some Si—N bonds are formed. In some cases, x may vary from about 0.9 to about 1.7, from about 1.0 to about 1.5, or from about 1.2 to about 1.4. In some embodiments, silicon nitride is formed where Si has an oxidation state of +IV and the amount of nitride in the material may vary.

In this disclosure, “continuously” can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

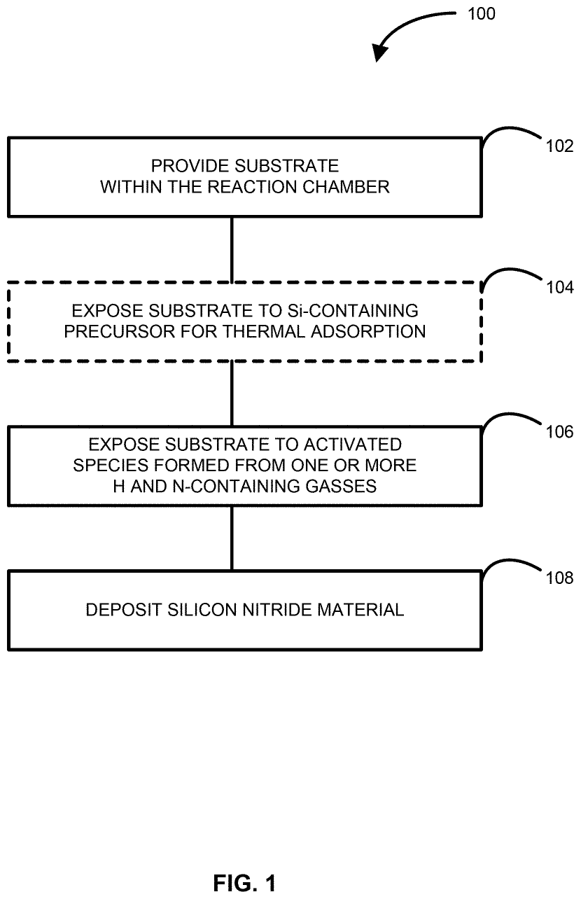

Turning now to the figures, FIG. 1 illustrates a method 100 of forming a silicon nitride layer in accordance with exemplary embodiments of the disclosure. Method 100 includes the steps of providing a substrate within a reaction chamber (step 102), optionally exposing the substrate to a silicon-containing precursor (step 104), treating a surface of a substrate by exposing the substrate to activated species formed from one or more hydrogen and nitrogen containing gases (step 106), and depositing a silicon nitride layer on the surface of the substrate (step 106).

During step 102, a substrate is provided into a reaction chamber of a reactor. In accordance with examples of the disclosure, the reaction chamber can form part of a cyclical deposition or an atomic layer deposition (ALD) reactor. Exemplary single substrate reactors, suitable for use with method 100, include reactors designed specifically to perform ALD processes, which are commercially available from ASM International NV (Almere, The Netherlands). Exemplary suitable batch ALD reactors are also commercially available from ASM International NV. Various steps of method 100 can be performed within a single reaction chamber or can be performed in multiple reaction chambers, such as reaction chambers of a cluster tool—e.g., without exposing the surface of the substrate to an ambient atmosphere. A reactor including the reaction chamber can be provided with a heater to activate the reactions by elevating the temperature of one or more of the substrate and/or the reactants/precursors.

During step 102, the substrate can be brought to a desired temperature and pressure for step 104 and/or step 106. By way of examples, a temperature (e.g., of a substrate or a substrate support) within a reaction chamber can be between about 50° C. and about 700° C. or about 200° C. and about 500° C. A pressure within the reaction chamber can be about 0.1 to about 50 Torr.

The substrate provided during step 102 can include a surface that includes one or more materials—sometimes referred to herein as material surfaces. Exemplary materials include semiconductor (e.g., Group IV) material; metal; oxides, such as silicon oxides; metal oxides; metal nitrides; semiconductor (e.g., Group IV) nitrides, such as silicon nitrides and silicon oxynitrides, other dielectric materials, and any combination of such materials, any of which can be thermally deposited or deposited with the assistance of a plasma.

Step 104 can be used to, for example, improve efficiency of or reduce an overall time of method 100. For example, a total process time to deposit a silicon nitride film, including pretreatment, may be reduced by using step 104 of method 100. In accordance with examples of the disclosure, the substrate can be exposed to a silicon-containing precursor during step 104 to, for example, adsorb silicon containing molecules on a surface of the substrate, such that the surface is terminated with Si—H bonds. The Si—H bonds can be used to, for example, form one or more undercoordinated Si═N, SiNH₄, or Si—NH₂ bonds on the surface of the substrate during a subsequent pretreatment step.

In accordance with various examples of the disclosure, the silicon precursor is thermally adsorbed or thermally reacts with a surface of a substrate. In other words, the silicon precursor is not exposed to a plasma process during step 104. Silicon precursors suitable for use with step 104 can include silicon and hydrogen, such as silanes, such as silane, disilane, trisilane, compound comprising a silane, or the like. A flowrate of the silicon precursor into the reaction chamber can range from, for example, about 10 sccm to about 5 slm. A carrier gas, such as nitrogen, can be co-flowed with the silicon precursor. A flowrate of the carrier into the reaction chamber can range from, for example, about 0 slm to about 50 slm. A pressure within the reaction chamber during step 104 can be between about 0.1 Torr and about 50 Torr. A temperature of a substrate can be between about 50° C. and about 700° C. A silicon precursor can be flowed to the reaction chamber for a period of about 0.05 sec to about 10 min. Then, the flows of silicon precursor and carrier can cease and the reaction chamber can be purged.

During step 106, the substrate is exposed to activated species formed from one or more gases comprising nitrogen and hydrogen. During this step, N—H and/or N—H₂ groups can form on a surface of the substrate. The formation of such groups on the surface of the substrate facilitates subsequent (e.g., CVD or cyclic) deposition of silicon nitride on the surface of the substrate, even when the surface comprises different materials.

By way of examples, substrate surfaces can include native oxide and/or thick silicon oxide film. Without pretreatment (e.g., optionally step 104 and step 106), as described herein, an incubation period for plasma-enhanced deposition of silicon nitride can be highly dependent on a quality of an underlying layer. For example, deposition of silicon nitride over a native silicon oxide can be achieved with relatively low incubation, while incubation of silicon nitride over a thick, high quality silicon oxide film can exhibit a much higher incubation. However, use of step 106, alone or in combination with step 104, can reduce or eliminate the incubation period over both surfaces, thereby allowing for more uniform deposition of silicon nitride over the surfaces—whether on the same or on different substrates. In accordance with examples of the disclosure, when one or more substrates have multiple material surfaces to be pretreated, a pretreatment time is selected to be greater than a minimum pretreatment of a surface with the longer pretreatment time, such that the surface termination across the material surfaces is substantially similar. In accordance with at least some embodiments of the disclosure, an incubation difference between two or more material surfaces is less than 0.5 nm. In some cases, the pretreatment time can be less than 45 seconds. As discussed in more detail below, another advantage of methods described herein is that a uniformity of a silicon nitride film deposited over a feature on or within a substrate can be improved. By way of examples, the silicon nitride may be deposited over the one or more features, i.e., high aspect ratio features (e.g., having an aspect ratio greater than or equal to 10 or 12), with a step coverage greater than approximately 90%, or greater than approximately 95%, or greater than approximately 99%, or even substantially equal to 100%. As used herein, the term “step coverage” is defined as percentage ratio of a thickness of the metal oxide film on a sidewall of a feature (e.g., trench or protrusion) to the thickness of the metal oxide on a horizontal surface of the substrate. In these cases, a time period of the pretreatment processes can be selected to obtain the desired step coverage. In accordance with further examples, the pretreatment results in substantially uniform surface bonding states of the treated surface.

In accordance with examples of the disclosure, one or more gases including nitrogen and hydrogen include at least one of nitrogen (N₂) and hydrogen (H₂)—e.g., nitrogen or a mixture of nitrogen and hydrogen. Respective concentrations of nitrogen and hydrogen can be selected, such that an amount of nitrogen reactive species is saturated. In accordance with particular examples, the one or more gases including nitrogen and hydrogen include greater than about 0.3 volumetric (V) percent hydrogen or about a few V % (e.g., 2 V % or more) to about 100 V % percent hydrogen in nitrogen. Unless otherwise noted, percentages of a gas refer to volumetric percentages.

In some cases, the one or more gases including nitrogen and hydrogen can include one or more of ammonia and hydrazine. In some cases, the one or more gases including nitrogen and hydrogen can further include a second gas. The second gas can include one or more of argon, helium, and nitrogen. A mixture including a second gas can include about 0 to about almost 100 percent of the second gas. By way of illustration, the one or more gases including nitrogen and hydrogen can include nitrogen and hydrogen, nitrogen and ammonia, nitrogen, hydrogen, and ammonia, or any of these with one or more of helium and argon.

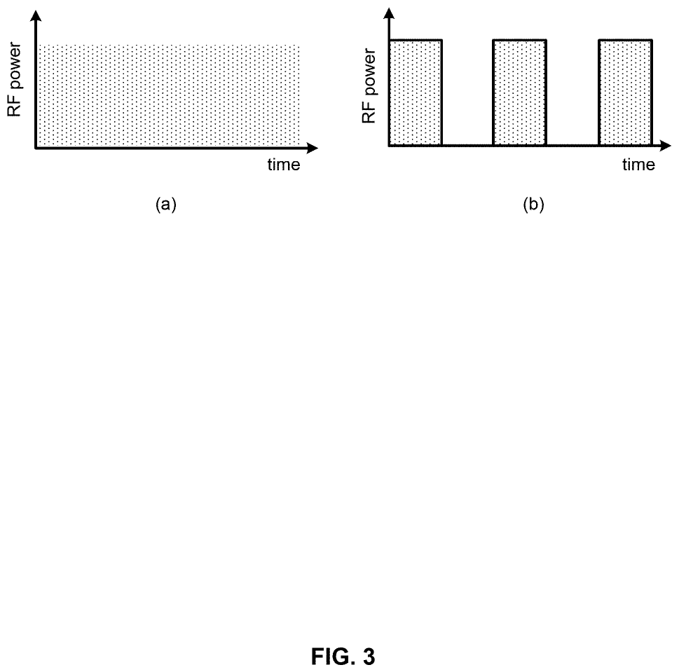

In some cases, it may be desirable to pulse plasma-formation power to, for example, reduce any damage to a substrate surface that may occur during a pretreatment process, while still achieving lower incubation and relatively high throughput. FIG. 3(a) illustrates constant power applied during a pretreatment step. FIG. 3(b) illustrates pulsed power applied during step 106. An on power on duration can range from about 10% to about 90%. An off power on duration can range from about 10% to about 90%. A pulse frequency can range from about 1000 Hz to about 100000 Hz. An on-time duty ratio can be greater than 50%. A frequency of power used to form a plasma during the step of exposing the substrate to activated species 106 can be between about 100 kHz and about 2.45 GHz.

During step 108, silicon nitride is deposited onto the pretreated surface of the substrate. In accordance with examples of the disclosure, step 108 is performed without a vacuum break or without exposure of the substrate to an ambient atmosphere. In accordance with further examples, step 108 is performed within the same reaction chamber used for one or more of steps 102-106. In embodiments where different reaction chambers are utilized for steps 106 and 108, the substrate may be transferred from a first reaction chamber (for pretreatment) to a second reaction chamber (for silicon nitride deposition) without exposure to the ambient atmosphere. In other words, methods of the disclosure may comprise treating the material and forming the silicon nitride film on the substrate in the same semiconductor processing apparatus. The semiconductor processing apparatus utilized for steps 106 and 108 may comprise a cluster tool which comprises two or more reaction chambers and which may further comprise a transfer chamber through which the substrate may be transported between the first reaction chamber and the second reaction chamber. In some embodiments, the environment within the transfer chamber may be controlled, i.e., the temperature, pressure and ambient gas can be controlled, such that the substrate is not exposed to the ambient atmosphere after step 106 and before step 108. Similarly, when step 104 is employed, the substrate may not be exposed to an ambient environment between steps 104 and 106.

Depositing a layer of silicon nitride step 108 can include CVD or a cyclical deposition process. A cyclic (e.g., an ALD) cycle can include exposing the substrate to a precursor (also referred to as a reactant), removing any unreacted precursor and/or reaction byproducts from a reaction space and exposing the substrate to a reactant, followed by a second removal step. The precursor can include, for example, a halogen-based precursor. Exemplary silicon halides include silicon tetraiodide (SiI₄), silicon tetrabromide (SiBr₄), silicon tetrachloride (SiCl₄), hexachlorodisilane (Si₂Cl₆), hexaiododisilane (Si₂I₆), and octoiodotrisilane (Si₃I₈). In some cases, the precursor can include the same or similar precursor used during step 104. The second reactant can include a nitrogen source, such as nitrogen gas, ammonia, hydrazine, or an alkyl-hydrazine, wherein the alkyl-hydrazine may refer to a derivative of hydrazine which may comprise an alkyl functional group and may also comprise additional functional groups. Non-limiting example embodiments of an alkyl-hydrazine may comprise at least one of tertbutylhydrazine (C₄H₉N₂H₃), methylhydrazine (CH₃NHNH₂) or dimethylhydrazine ((CH₃)₂N₂NH₂). A hydrogen-containing gas, such as hydrogen, can be introduced to the reaction chamber with the nitrogen gas. In accordance with at least some examples of the disclosure, a plasma is not formed while flowing the precursor into the reaction chamber.

During the purge steps, precursors/reactants can be temporally separated by inert gases, such as argon (Ar), nitrogen (N₂) or helium (He) and/or a vacuum pressure to prevent or mitigate gas-phase reactions between reactants and enable self-saturating surface reactions. In some embodiments, however, the substrate may be moved to separately contact a first vapor phase reactant and a second vapor phase reactant. Because, for example, in the case of ALD, the reactions can self-saturate, strict temperature control of the substrates and precise dosage control of the precursors may not be required. However, the substrate temperature may desirably be such that incident gas species do not condense into monolayers or multimonolayers nor thermally decompose on the surface.

In some embodiments, providing a silicon-source precursor may comprise pulsing one or more silicon precursors over the substrate for a time period of between about 0.5 seconds and about 30 seconds, or between about 0.5 seconds and about 10 seconds, or between about 0.5 seconds and about 5 seconds. In addition, during the pulsing of the silicon halide source over the substrate, the flow rate of the silicon halide source may be less than 2000 sccm.

In some embodiments, providing a reactant may comprise pulsing the one or more reactants over the substrate for a time period of between about 0.5 seconds to about 30 seconds, or between about 0.5 seconds to about 10 seconds, or between about 0.5 seconds to about 5 seconds. During the pulsing of the nitrogen source over the substrate, the flow rate of the nitrogen source may be less than 4000 sccm, or less than 2000 sccm, or less than 1000 sccm, or even less than 250 sccm.

In accordance with further examples of the disclosure, depositing a layer of silicon nitride 108 can include formation of activated species. For example, step 108 can include formation of activated reactant species by forming a plasma while flowing a reactant into the reaction chamber. The plasma can be formed using, for example, a capacitively coupled plasma (CCP) source, an inductively coupled plasma (ICP) source or a remote plasma (RP) source. A power used to produce the plasma can range from about 10 W to about 4 kW or about 400 W to about 1 kW. A time (e.g., a time of the activated plasma) for step 108 can range from about 1 millisecond to about 5 minutes. A frequency of power used to form a plasma during the step of forming activated reactant species within the reaction chamber can be between about 100 kHz and about 2.45 GHz

A cyclical deposition (e.g., ALD) process of depositing a layer of silicon nitride (step 108) may be repeated one or more times until the desired thickness of a silicon nitride layer is achieved. The cyclical deposition process can be used to form a silicon nitride film with a thickness of between approximately 0.3 nm and approximately 30 nm or about 1 nm and about 10 nm.

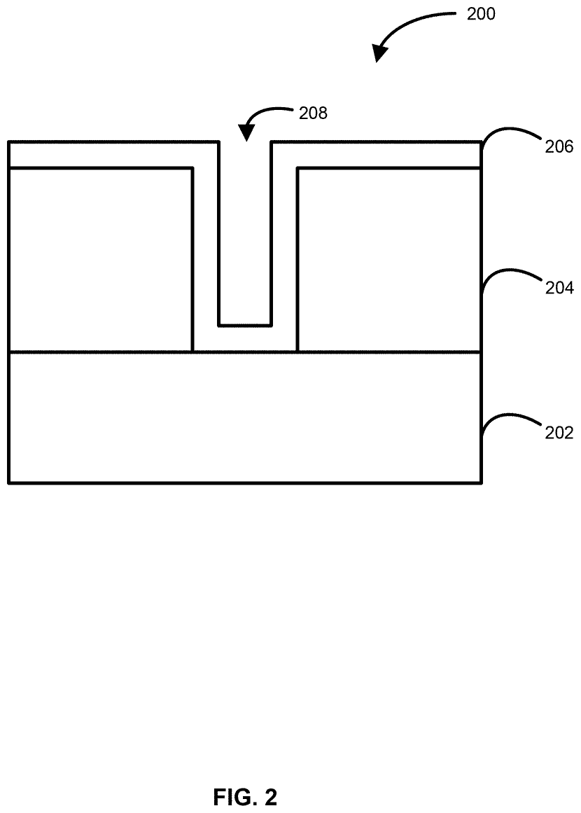

FIG. 2 illustrates a structure 200 in accordance with exemplary embodiments of the disclosure. Structure 200 includes a substrate 202, a material 204 having a trench 208 formed therein, and a layer of silicon nitride 206 deposited within trench (feature) 208.

Substrate 202 can include any suitable material, such as semiconductor material and materials typically used to form semiconductor devices. By way of example, substrate 202 can be or include silicon, other Group IV semiconductor material, a Group III-V semiconductor, and/or a Group II-VI semiconductor.

Material 204 can include any of the substrate materials noted above. For example, material 204 can include an oxide, such as a Group IV or metal oxide, or a nitride, such as a Group IV or metal nitride. Silicon nitride layer 206 can include a silicon nitride layer deposited using a PEALD process, such as a PEALD process as described herein.

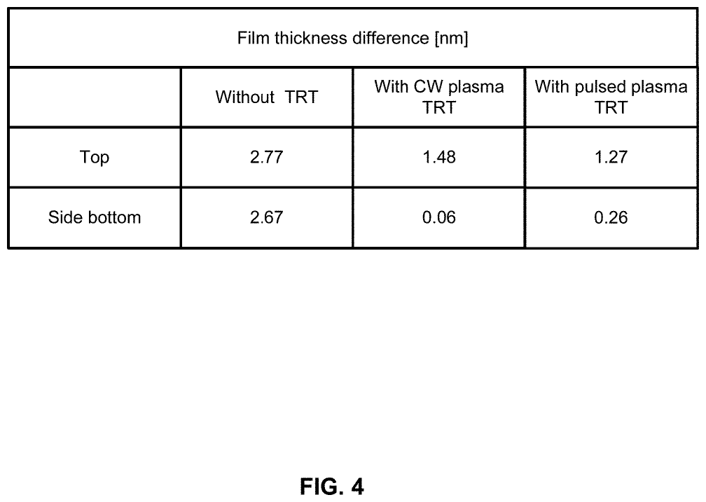

FIG. 4 illustrates film thickness measurement differences of silicon nitride films deposited overlying silicon and silicon oxide features for structures formed without pretreatment, structures formed with constant power applied during, and structures formed with pulsed power applied during pretreatment. This illustrative data indicates that film thickness differences between films deposited within SiO trenches and silicon trenches without a pretreatment are significantly greater than films deposited with constant-power or pulsed-power pretreatment.

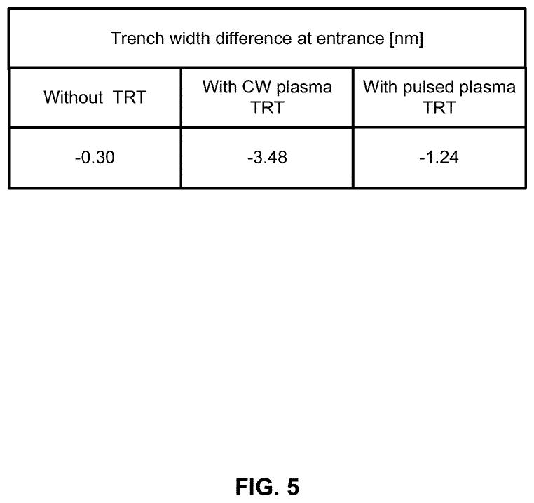

FIG. 5 illustrates film thickness measurements, showing an amount of trench reduction at an entrance of the trench for process without pre-treatment and pre-treatment by constant power plasma and pulsed-plasma processes. As illustrated, an amount of trench reduction at an entrance of the feature for a process without pretreatment is less than the reduction for pulsed-power pretreatment, which is less than the reduction for constant-power pretreatment.

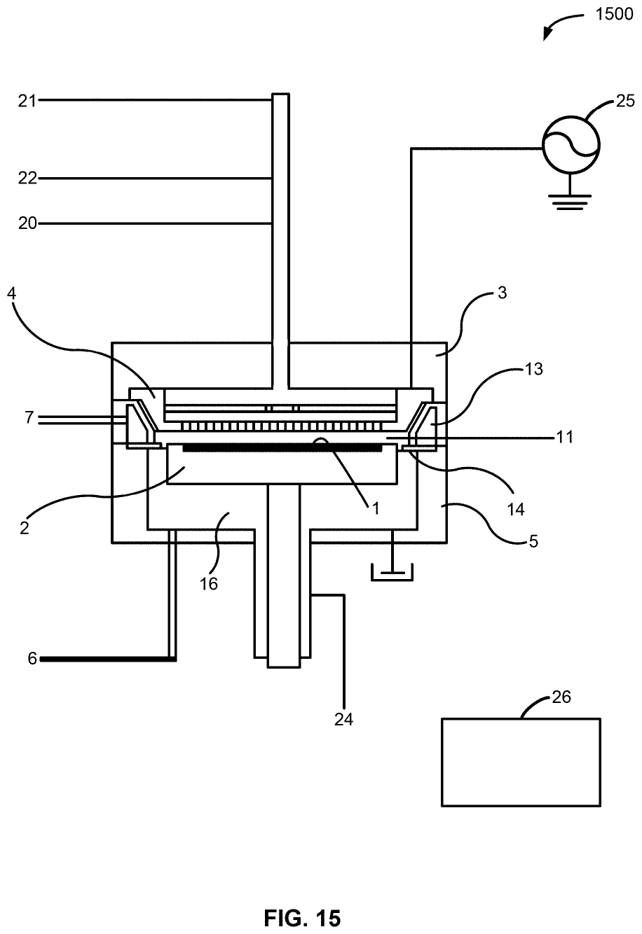

Turning now to FIG. 15, a reactor system 1500 is illustrated in accordance with exemplary embodiments of the disclosure. Reactor system 1500 can be used to perform one or more steps or sub steps as described herein and/or to form one or more structures or portions thereof as described herein.

Reactor system 1500 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 100 kHz, 13.56 MHz, 27 MHz, 2.45 GHz, or any values therebetween) from power source 25 to one electrode (e.g., electrode 4) and electrically grounding the other electrode (e.g., electrode 2). A temperature regulator is provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, or the like can be introduced into reaction chamber 3 using one or more of a gas line 20, a gas line 21, and a gas line 22, respectively, and through the shower plate 4. Although illustrated with three gas lines, reactor system 1500 can include any suitable number of gas lines.

In reaction chamber 3, a circular duct 13 with an exhaust line 7 is provided, through which gas in the interior 11 of the reaction chamber 3 can be exhausted. Additionally, a transfer chamber 5, disposed below the reaction chamber 3, is provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone is provided (a gate valve through which a substrate is transferred into or from the transfer chamber 5 is omitted from this figure). The transfer chamber is also provided with an exhaust line 6. In some embodiments, the deposition and/or surface treatment steps are performed in the same reaction space, so that two or more (e.g., all) of the steps can continuously be conducted without exposing the substrate to air or other oxygen-containing atmosphere.

In some embodiments, continuous flow of a carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber, and can carry the precursor gas in pulses by switching between the main line and the detour line, without substantially fluctuating pressure of the reaction chamber.

Reactor system 1500 can include one or more controller(s) 26 programmed or otherwise configured to cause one or more method steps as described herein to be conducted. Controller(s) 26 are coupled with the various power sources, heating systems, pumps, robotics and gas flow controllers, or valves of the reactor, as will be appreciated by the skilled artisan.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

### SPECIFIC EXAMPLES

The examples provided below are meant to be illustrative only. The examples are not meant to limit the scope of the disclosure or claims.

### Example 1

### N₂/H₂ Pretreatment

Two blanket samples (a silicon substrate and a substrate having a thermal silicon oxide layer thereon) are introduced in the deposition reactor. The samples were heated by being mounted on a susceptor heater that was heated to a temperature of 450° C. The gap between a lower electrode (the susceptor heater) and an upper electrode (the showerhead, gas introduction system) was 12 mm. The pressure was increased by introduction of nitrogen and hydrogen up to 350 Pa. A total flow-rate is 10 slm and H₂ concentration was varied between 0%, 0.3%, 3% and 10%. 1.5 slm of N₂ was introduced from a bottom of the reaction chamber to prevent or mitigate hydrogen gas introduction below the susceptor unit. A HRF power of 600 W was applied between the upper and lower electrodes for a duration of 30 seconds, 60 seconds, 1.5 minutes, or 2 minutes. Nitrogen flow-rate was increased to 12 slm and H₂ flow-rate was adjusted to 5 sccm. The pressure in the reaction chamber was increased to 2000 Pa and the gap kept to 12 mm. The below steps were repeated to achieve desired film thickness deposition:

Silicon precursor was introduced in the chamber through a pipe heated at 75° C. using 2 slm of N₂ carrier gas. The feed time was 0.3 second.

The reaction chamber was purged for 1 second using N₂ gas flow.

800 W RF power is turned on for 1.6 seconds. During this time, the reactant (nitrogen) continues to flow.

The reaction chamber is purged for 0.1 second.

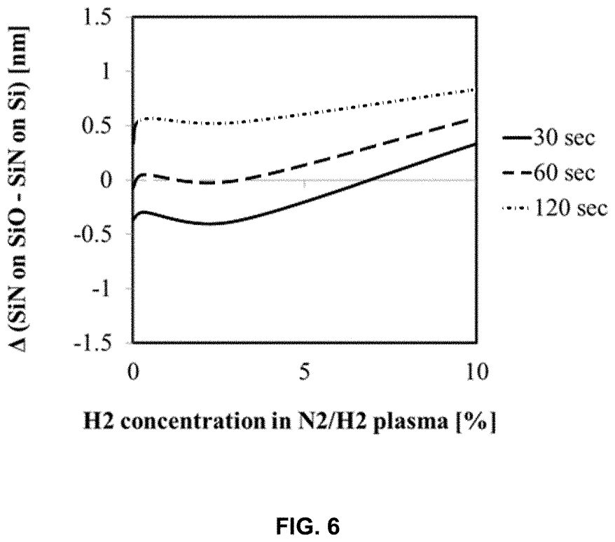

FIG. 6 illustrates the evolution of the thickness difference between silicon thermal oxide and silicon blankets for different treatment times and concentrations of H₂ in nitrogen. It can be observed that increasing the pretreatment time reduces the thickness difference regardless of the hydrogen concentration. Also, the introduction of a large hydrogen content of, for example, more than 3% was used to obtain advantages over pure nitrogen plasma treatment.

### Example 2

### 10%-20% Hydrogen in Nitrogen Plasma Pretreatment

Two trench-patterned samples (silicon substrate and substrate with silicon oxide) were introduced in a reaction chamber of a reactor. Both of the substrates include trench structures having an aspect ratio of 12. The substrates were mounted on a susceptor heater and heated to a temperature of 450° C. A gap between the lower electrode (the susceptor heater) and upper electrode (the showerhead, gas introduction system) was 12 mm. A pressure is increased by introduction of nitrogen and hydrogen up to 350 Pa. A total flow-rate was 5 slm or 10 slm and H₂ flow-rate was fixed at 1 slm. 1.5 slm of N₂ was introduced from the bottom of the reactor to mitigate/prevent hydrogen gas introduction below the susceptor unit. A HRF power of 800 W was applied between the upper and lower electrodes for different durations between 0 second and 150 seconds. Nitrogen flow-rate was increased to 12 slm and H₂ flow-rate adjusted to 5 sccm. The pressure was increased to 2000 Pa and the gap kept to 12 mm.

The below deposition steps were repeated to achieve desired film thickness.

Silicon precursor was introduced in the chamber through a pipe heated at 75° C. using 2 slm of N₂ carrier gas. The feed time was 0.3 second.

The reaction chamber was purged for 1 second using N₂ gas flow.

800 W RF power is turned on for 1.6 second.

The reaction chamber was purged for 0.1 second.

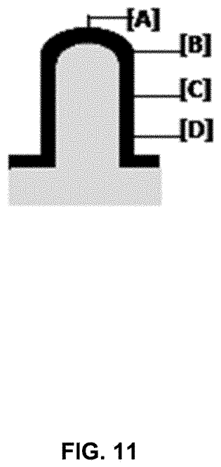

After the final deposition cycle, the reaction chamber was purged and vacuumed and the samples were taken out from the reactor. The samples were then analyzed by STEM. Locations A-D are illustrated in FIG. 11.

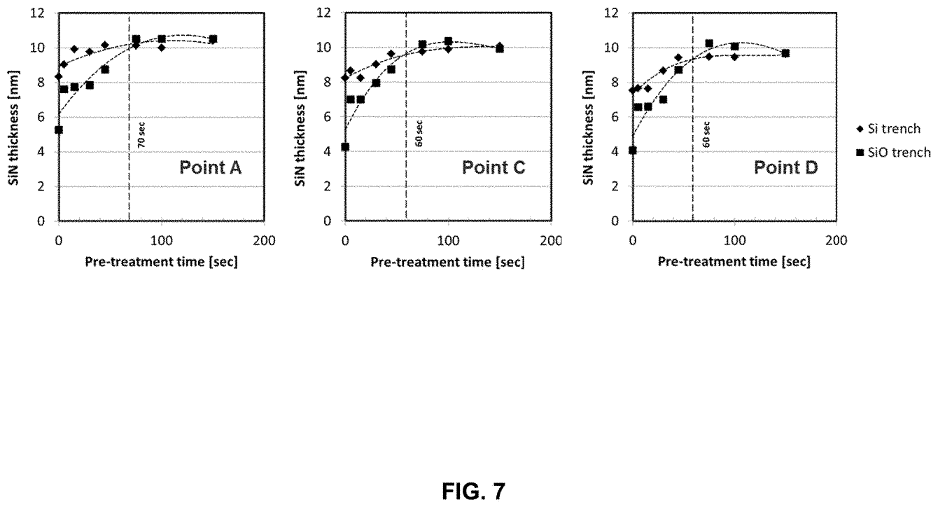

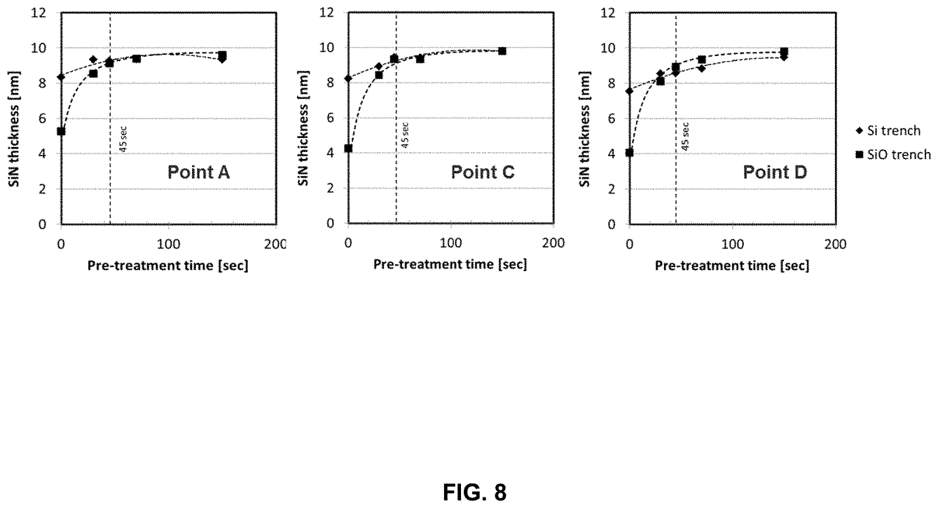

FIGS. 7 and 8 illustrate the evolution of the top and sidewall thicknesses for different pretreatment times and H₂ concentrations, respectively 10% and 20%. It can be seen that a treatment duration of around 70 seconds may be desired to eliminate the growth incubation of both silicon and silicon oxide trenches for a H₂ concentration of 10% (FIG. 7). This treatment duration can be reduced to 45 seconds for a 20% H₂ concentration (FIG. 8). Also, it can be observed that, compared to without pretreatment, the thickness difference between points A, C and D could be reduced, and thus high step coverage is observed.

### Example 3

### OES Analysis During N₂/H₂ Plasma Pretreatment

The susceptor heater was heated to 450° C., the upper electrode was heated to 200° C., and the chamber wall was heated to 150° C. The gap between the lower electrode (the susceptor heater) and upper electrode (the showerhead, gas introduction system) was 12 mm.

The pressure within the reaction chamber was increased by introduction of nitrogen and hydrogen up to 350 Pa. A total flow-rate was 5 slm or 10 slm and H₂ concentration was varied between 0% and 20%. 1.5 slm of N₂ was introduced from the bottom of the reactor to prevent/mitigate hydrogen gas introduction below the susceptor unit.

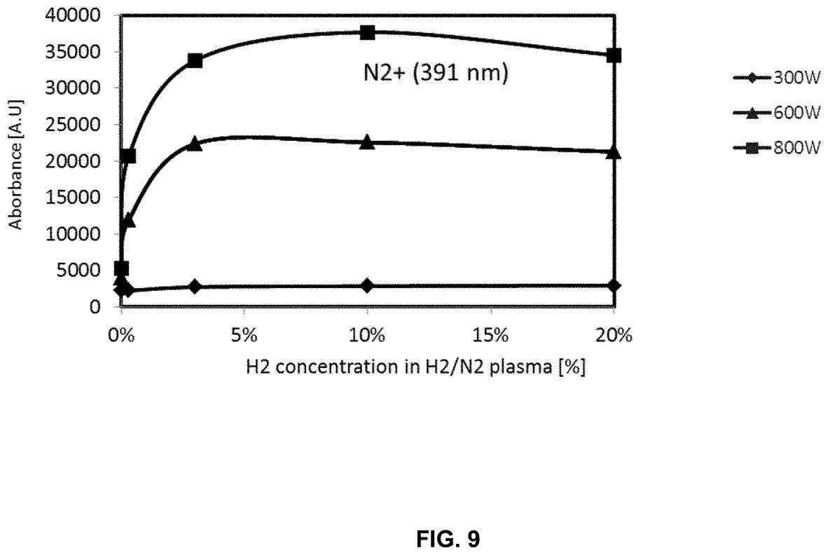

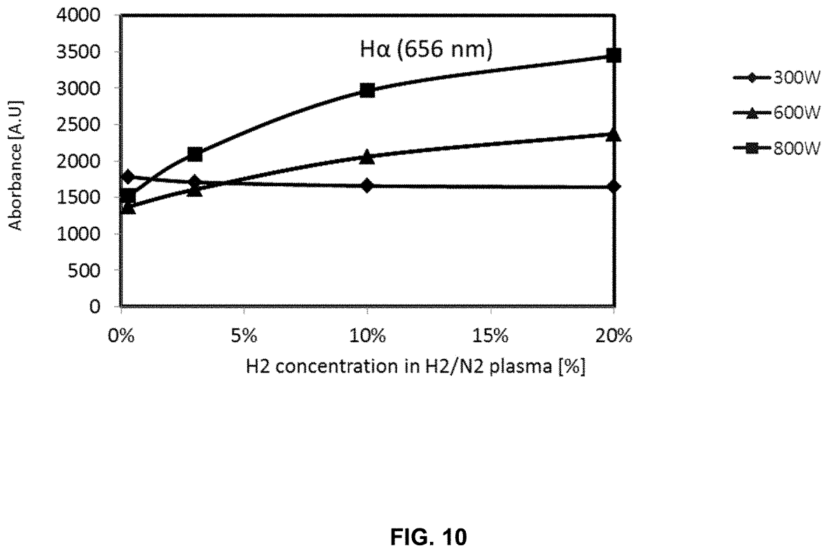

A HRF power of 300 W or 600 W was applied between the upper and lower electrodes for 45 seconds. An optical emission spectroscopy (OES) unit was used to analyze emitted reactive species during plasma treatment and connected to the chamber through an optical fiber unit fixed on the chamber wall view port. With reference to FIG. 9, it can be observed that N₂₊ (emission wavelength: 391 nm) emission is deeply linked to H₂ concentration. Emission is increased compared to pure N₂ plasma and is saturated from a few % of H₂. Emission of reactive species derived from H₂, as Hα (emission wavelength: 656 nm), is favored when increasing HRF power, as illustrated in FIG. 10. No saturation behavior is observed, which means that increasing H₂ ratio is an efficient way to increase Hα species.

### Example 4

### Ar/NH₃ Plasma Pretreatment with SiN PEALD Process

Two trench-patterned samples (a silicon substrate and a substrate having a layer of SiOₓ thereon) are introduced into a reaction chamber of a reactor. Both substrates include trench structures (features) having an aspect ratio of 10.

The samples were heated by heating a susceptor heater to 450° C. The gap between the lower electrode (the susceptor heater) and an upper electrode (the showerhead, gas introduction system) was 10 mm. A pressure within the reaction chamber was increased by introduction of 6.75 slm of argon and 0.25 slm of ammonia to 300 Pa. 1.5 slm of N₂ was introduced from the bottom of the reactor to prevent/mitigate argon and ammonia gas introduction below the susceptor unit.

A HRF power of 300 W was applied between the upper and lower electrodes for a duration 1 of 45 s or 2 of 230 s. Argon and ammonia flow are gradually stopped and a flow of 12 slm of N₂ and 5 sccm of H₂ was introduced into the reaction chamber. The pressure within the reaction chamber was then increased to 2000 Pa and the gap to 12 mm.

The below steps were repeated to achieve desired film thickness deposition:

Silicon precursor was introduced in the chamber through a pipe heated at 75° C. using 2 slm of N₂ carrier gas. The feed time was 0.3 seconds.

The reaction chamber was then purged for 1 second using N₂ gas flow.

800 W RF power was turned on for 1.6 seconds.

The reaction chamber was then purged for 0.1 second.

After deposition was completed, the chamber was purged and vacuumed and the samples are taken out from the reactor.

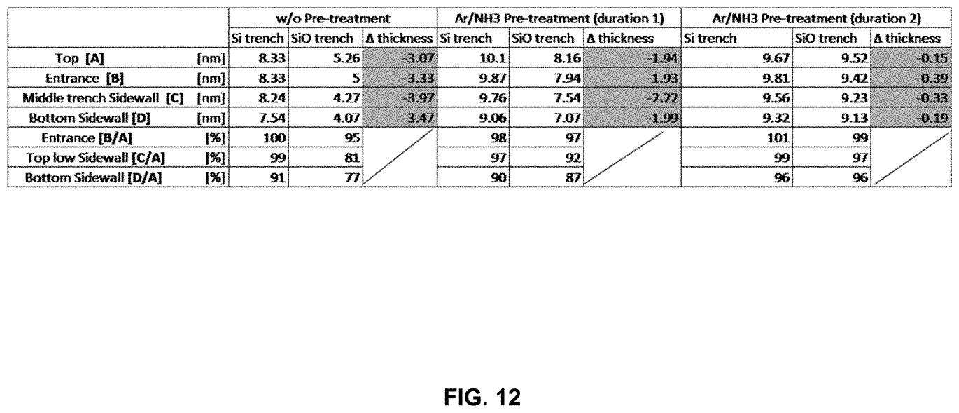

The samples were analyzed by scanning transmission electron microscopy (STEM). FIG. 12 illustrates the evolution of top and sidewall film thicknesses when increasing the pretreatment time. As shown, without pretreatment, around 3 nm difference exists between the film deposited on the silicon substrate and the substrate including a layer of SiOₓ; this difference is reduced to 2 nm for a pretreatment duration 1 and less than 0.5 nm for a duration 2. It is also noted that good uniformity of the film thickness on each structure is obtained for duration 2 pretreatment time. In FIG. 12, duration 1 is 45 sec and duration 2 is 230 sec.

### Example 5

### N₂/NH₃ Plasma Pretreatment Before SiN PEALD Process

Two trench-patterned samples (a silicon substrate and a substrate having SiOₓ thereon) are introduced into a reaction chamber. Both substrates include trench structures having an aspect ratio of 10.

The samples were heated by heating a susceptor heater to 450° C. A gap between the lower electrode (the susceptor heater) and upper electrode (the showerhead, gas introduction system) was 12 mm.

The pressure in the reaction chamber was increased by introduction of 9.75 slm of nitrogen and 0.25 slm of ammonia up to 350 Pa. 1.5 slm of N₂ was introduced from the bottom of the reactor to prevent/mitigate ammonia gas introduction below the susceptor unit.

A HRF power of 520 W was applied between the upper and lower electrodes for a duration 1 of 45 s or 2 of 240 s.

Ammonia flow was gradually stopped, N₂ flow was increased to 12 slm, and a flow of 5 sccm of H₂ was introduced in the reaction chamber. The pressure within the reaction chamber was increased to 2000 Pa and the gap kept to 12 mm.

The below steps were repeated to achieve desired film thickness deposition:

Silicon precursor was introduced in the reaction chamber through a pipe heated at 75° C. using 2 slm of N₂ carrier gas. The feed time is 0.3 second.

The reaction chamber was purged for 1 second using N₂ gas flow.

800 W RF power was turned on for 1.6 seconds.

The reaction chamber was purged for 0.1 second.

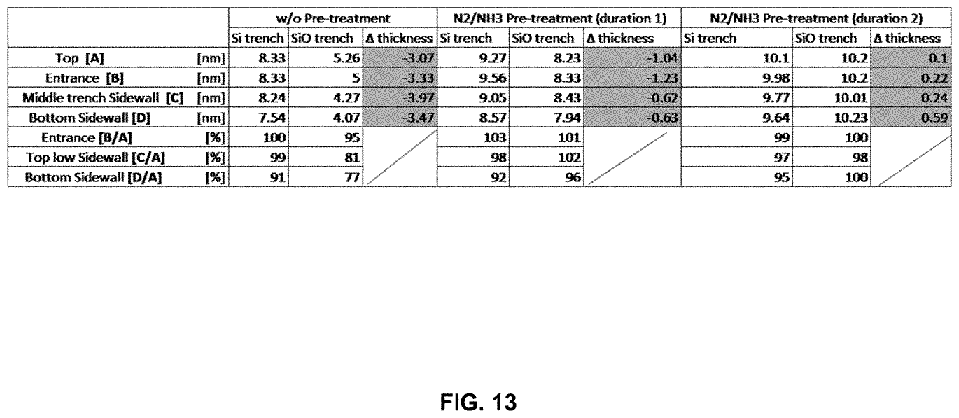

After deposition was complete, the chamber was purged and vacuumed and the samples were taken out from the reactor. The samples were then analyzed by STEM. FIG. 13 illustrates the evolution of top and sidewall film thicknesses when increasing the pretreatment time. Without pretreatment, around 3 nm difference exists between the film deposited on the silicon substrate and the substrate including SiOₓ; this difference is reduced to around 1 nm for a pretreatment duration 1 and less than 0.6 nm for a duration 2. It is also noted that good uniformity of the film thickness on each structure is obtained for duration 1 and 2 pretreatment times. In FIG. 13, duration 1 is 45 sec and duration 2 is 240 sec.

### Example 6

### Comparison of Ar/NH₃ Plasma Pretreatment Only and Combination of Silane Thermal Adsorption and Ar/NH₃ Plasma Pretreatment

Two trench-patterned samples (a silicon substrate and a substrate having SiOₓ thereon) are introduced into a reaction chamber. Both substrates include trench structures having an aspect ratio of 10.

The samples were heated by heating a susceptor heater to 450° C. A gap between the lower electrode (the susceptor heater) and upper electrode (the showerhead, gas introduction system) was 10 mm.

A pressure was to 2000 Pa by introduction of 4 slm of nitrogen and 100 sccm of silane. Once pressure was stabilized, the flow of nitrogen and silane continued for 15 seconds. Then, the gas flows were stopped and the reaction chamber was purged.

A pressure within the reaction chamber was increased by introduction of 6.75 slm of argon and 0.25 slm of ammonia up to 300 Pa. 1.5 slm of N₂ was introduced from the bottom of the reactor to prevent/mitigate argon and ammonia gas introduction below the susceptor unit.

A HRF power of 300 W was applied between the upper and lower electrodes for a duration 1 of 45 s. Argon and ammonia flows were gradually stopped and a flow of 12 slm of N₂ and 5 sccm of H₂ was introduced into the reaction chamber. The pressure within the reaction chamber was then increased to 2000 Pa and the gap to 12 mm.

The below steps were repeated to achieve desired film thickness.

Silicon precursor was introduced in the chamber through a pipe heated to 75° C. using 2 slm of N₂ carrier gas. The feed time was 0.3 second.

The reaction chamber was purged for 1 second using N₂ gas flow.

800 W RF power was turned on for 1.6 seconds.

The reaction chamber was then purged for 0.1 second.

After deposition was completed, the chamber was purged and the samples were taken out from the reactor.

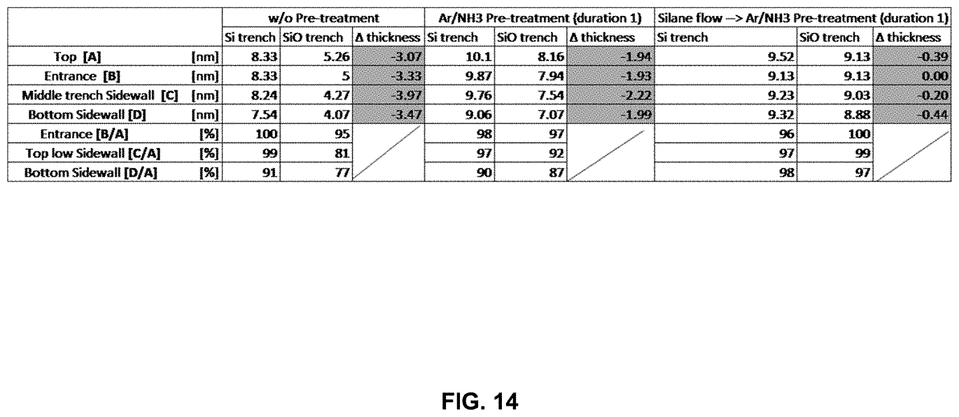

The samples were analyzed by STEM. FIG. 14 illustrates the evolution of top and sidewall film thicknesses with or without the addition of silane thermal adsorption step. Without silane adsorption step, around 2 nm difference exists between the film deposited on the silicon substrate and the substrate including SiOₓ for a pretreatment duration 1; the incubation is reduced to less than 0.5 nm when adding the silane adsorption step. It is also noted that good step coverage is maintained. In FIG. 14, duration 1 is 45 sec.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a silicon nitride layer, the method comprising the steps of:
providing a substrate within a reaction chamber;
exposing the substrate to activated species formed from one or more gases comprising nitrogen and hydrogen; and
depositing a layer of silicon nitride on the substrate within the reaction chamber.

2. The method of claim 1, wherein the one or more gases comprising nitrogen and hydrogen comprise a nitrogen-containing gas and a hydrogen-containing gas.

3. The method of claim 2, wherein the nitrogen-containing gas comprises nitrogen.

4. The method of claim 2, wherein the hydrogen-containing gas comprises hydrogen.

5. The method of claim 1, wherein the one or more gases comprising nitrogen and hydrogen comprise one or more of ammonia, hydrazine, and a second gas.

6. The method of claim 5, wherein the second gas comprises one or more of argon, helium, and nitrogen.

7. The method of claim 1, wherein the step of depositing a layer of silicon nitride comprises a plasma-enhanced deposition process.

8. The method of claim 7, wherein the plasma-enhanced deposition process comprises:
providing a precursor to the reaction chamber;
purging the reaction chamber;
forming activated reactant species within the reaction chamber; and
purging activated reactant species.

9. The method of claim 8, wherein a reactant is continuously flowed during the steps of providing a precursor to the reaction chamber and forming activated reactant species within the reaction chamber.

10. The method of claim 9, wherein the reactant is selected from the group consisting of nitrogen, hydrogen, and ammonia.

11. The method of claim 8, wherein the step of forming activated reactant species within the reaction chamber comprises forming activated species from one or more gases comprising nitrogen and hydrogen.

12. The method of claim 8, wherein a frequency of power used to form a plasma during the step of forming activated reactant species within the reaction chamber is between about 100 kHz and about 2.45 GHz.

13. The method of claim 8, wherein a power used to form a plasma during the step of forming activated reactant species within the reaction chamber is between about 10 W and about 4 kW.

14. The method of claim 1, wherein a frequency of power used to form a plasma during the step of exposing the substrate to activated species is between about 100 kHz and about 2.45 GHz.

15. The method of claim 1, wherein a power used to form a plasma during the step of exposing the substrate to activated species is between about 10 W and about 4 kW.

16. A method of forming a silicon nitride layer, the method comprising the steps of:
providing a substrate within a reaction chamber;
exposing the substrate to a silicon-containing precursor for thermal adsorption of silicon onto a surface of the substrate;
exposing the substrate to activated species formed from gases comprising nitrogen and hydrogen; and
depositing a layer of silicon nitride on the substrate within the reaction chamber.

17. The method of claim 16, wherein the silicon precursor comprises silicon and hydrogen.

18. The method of claim 16, wherein the step of depositing a layer of silicon nitride comprises a plasma-enhanced deposition process.

19. The method according to claim 1, wherein the step of exposing the substrate to activated species comprises a pulsed plasma process.

20. The method according to claim 19, wherein a power to produce a plasma is pulsed during the step of exposing the substrate to activated species.

21. A structure formed according to the method of claim 1.

22. A system for performing the steps of claim 1.
